(19) United States
(12) Patent Application Publication
(10) Pub. No.: US 2011/0291866 A1
(43) Pub. Date: Dec. 1, 2011

(54) VARIABLE-LENGTH DECODING DEVICE

(75) Inventors: Hideki KUROKI, Osaka (JP); Takeshi FURUTA, Kyoto (JP)

(73) Assignee: PANASONIC CORPORATION, Osaka (JP)

(21) Appl. No.: 13/207,722

(22) Filed: Aug. 11, 2011

Related U.S. Application Data
(63) Continuation of application No. PCT/JP2009/003542, filed on Jul. 28, 2009.

(30) Foreign Application Priority Data
Feb. 23, 2009 (JP) 2009-040034

(51) Int. Cl. H03M 7/40

(52) U.S. Cl. 341/67

(57) ABSTRACT

A variable-length decoding device includes a data determination unit which determines whether or not each of component values decoded by a variable-length decoding unit is a specific value; a data buffer that holds only a component value which is not the specific value; a last valid data determination unit which determines component values other than the last one of the component values not the specific value in a block; a flag buffer which holds flags each having a corresponding component value among the component values from the component value at the beginning of the block to the last component value and indicating whether or not the corresponding component value is the specific value; a flag buffer control unit which sets the flags; a data buffer control unit which controls writing in the data buffer; and a selecting unit which selects either zero or a coefficient read from the data buffer.

### CROSS REFERENCE TO RELATED APPLICATION

This is a continuation application of PCT application No. PCT/JP2009/003542 filed on Jul. 28, 2009, designating the United States of America.

### BACKGROUND OF THE INVENTION

(1) Field of the Invention

The present invention relates to variable-length decoding devices which decode coded data including a variable-length code into component values composing a block, and particularly to a variable-length decoding device that performs variable-length decoding, which is a fundamental process in coding and decoding of images.

(2) Description of the Related Art

Currently available methods of compressing and expanding videos are defined by various video coding standards, such as Moving Picture Expert Group (MPEG) including MPEG-1, MPEG-2, and MPEG-4, H.264/AVC, and VC-1, so that the methods of compressing and expanding videos support various image sizes and media. For example, a method according to the MPEG-1 or the MPEG-2 is used for media for relatively large size images, such as digital versatile discs (DVDs). On the other hand, a method according to the MPEG-4 or the H.264/AVC is used for media for relatively small image sizes, such as mobile phones or one-segment broadcasting, and a method according to the H.264/AVC or the VC-1 is used for media for relatively large image sizes such as high-definition television (HDTV) broadcasting. Today's rapid growth in popularity of HDTV and necessity for processing of high-definition images such as a 2K image or a 4K image create need for a more efficient image processing method.

FIG. 17 shows a typical process flow of image compression in a conventional technique. When a video is coded, the video is divided into units of processing. Each of the units is referred to as macroblock (MB). Each MB includes four luminance components and two chrominance components. The four luminance components are Y0, Y1, Y2, and Y3. The two chrominance components are Cb and Cr. Each of the Y components and C components is an 8×8 block which is composed of 64 pixel components.

The MPEG-1, MPEG-2, MPEG-4, H.264/AVC, and VC-1 involve some common processes, such as orthogonal transformation, variable-length coding, and quantization.

Orthogonal transformation 10 is a technique in which a video signal composed of space components is transformed into frequency components, and is performed for each of the blocks of Y0, Y1, Y2, Y3, Cb, and Cr. FIG. 18 illustrates frequency components of an orthogonally transformed block. Distribution of frequency components in data obtained by orthogonally transforming a natural image is uneven as shown in FIG. 18, and therefore the data is efficiently compressed by a method such as variable-length coding.

In quantization 11, which is performed using different methods depending on the coding standard, a quantization coefficient is generated by dividing an orthogonally-converted discrete cosine transform (DCT) coefficient by an externally determined quantization value. Because high-frequency DCT coefficients do not contribute to image quality so much, a quantized block has zero values concentratively among high-frequency DCT coefficients so that subsequent variable-length coding can be performed more efficiently.

Next, in variable-length coding 12, run-length data is generated by making combinations of RUN and LEVEL in a zigzag scanning order as shown in FIG. 19. The RUN indicates the number of zero values. The LEVEL indicates the magnitude of a coded coefficient. Data size is reduced by assigning codes having different lengths depending on the frequency of occurrence of each of the combinations.

FIG. 20 shows a typical process flow of image decoding in a conventional technique. The process flow includes variable-length decoding 20, inverse quantization 21, and inverse orthogonal transform 22 through which coded data obtained by image compression as shown in FIG. 18 is decoded.

In the variable-length decoding 20, variable-length coded data is decoded into combinations of RUN and LEVEL, zero values are generated according to the magnitude of RUN, and the generated zero values are combined with the LEVEL. This operation is performed for each 8×8 block. In the inverse quantization 21, the coded data of each 8×8 block thus obtained is multiplied by the quantization coefficient used in the quantization so that inverse quantization coefficients, which are data before the compression, are restored. In the inverse orthogonal transform 22, the generated inverse quantization coefficients are transformed from a frequency domain to a space domain so that the inverse quantization coefficients are decoded into image data.

The following describes a configuration of the variable-length decoding 20 in the conventional technique with reference to FIG. 21. FIG. 21 illustrates the configuration of the variable-length decoding 20 in the conventional technique. A variable-length decoding unit 401 receives variable-length code data from an input unit 400 and decodes variable-length code data into combinations of RUN and LEVEL. The RUN indicates the number of zero values. The LEVEL indicates the magnitude of a coefficient value. A write control unit 402 provides a selecting signal to a data selecting unit 403 such that the decoded RUN-number of zero values are written in a data buffer 405. After the decoded RUN-number of zero values is written in a data buffer 405, a coefficient indicated by the LEVEL is written in the data buffer 405. This operation is repeated until data of 8×8 pixels are generated. Next, a read control unit 404 reads the data from the data buffer 405 by zigzag scanning (see FIG. 19) and sends the data to a subsequent process unit 406 which performs inverse quantization 21. Such a configuration in the conventional technique has a problem that there are unproductive accesses to the data buffer due to writing the RUN-number of zero coefficients in series in the data buffer.

One of the solutions to the problem is a decode circuit for a run-length code disclosed in Japanese Unexamined Patent Application Publication Number 2006-74197 (Patent Reference 1). The following describes an example of the disclosed solution with reference to FIG. 22.

Referring to FIG. 22, an input unit 500 inputs variable-length coded and run-length coded data to a variable-length decoding unit 501. The variable-length decoding unit 501 decodes data input from the input unit 500 into combinations of RUN and LEVEL in sequence. The RUN indicates the number of zero values. The LEVEL indicates the magnitude of a coefficient value. The LEVEL is stored in a data buffer 508. An address adding unit 502 calculates, based on the number of zero values indicated by the RUN, an address of the LEVEL corresponding to the data. An information register 509 is an (M×N)-bit register which stores the result of the calculation performed by the address adding unit 502. A write control unit 503 stores the LEVEL in the data buffer 508 according to information from the address adding unit 502. A read control unit 504 reads the LEVEL from the data buffer 508 based on a value stored in the information register 509. A data selecting unit 505 outputs either the LEVEL stored in the data buffer 508 or a zero value based on the value stored in the information register 509. A subsequent process unit 506 performs a subsequent process on data received from the data selecting unit 505. An output unit 507 outputs data received from the subsequent process unit 506.

The variable-length decoding unit 501 receives the variable-length coded and run-length coded data from the input unit 500, and then decodes the variable-length coded and run-length coded data into combinations of RUN and LEVEL in sequence. The RUN indicates the number of zero values. The LEVEL indicates the magnitude of a coefficient value.

The address adding unit 502 calculates an address from the decoded data based on the magnitude of the decoded RUN, in the zigzag scanning order as shown in FIG. 19, that is, in the order of 1, 2, 9, 17 . . . . The information register 509 stores the RUN-number of zero values in series in the zigzag scanning order, and then stores an address of the LEVEL, for example, “1”, in a position following the zero values in the order. The write control unit 503 writes the LEVEL in a location according to the address calculated by the address adding unit 502. The write control unit 503 determines whether or not writing of the LEVEL for one block has been completed. When the write control unit 503 determines that writing of the LEVEL for one block has not been completed, the process returns to the first step of the decoding. When the write control unit 503 determines that writing of LEVEL for one block has been completed, the process proceeds to a step of reading. When the variable-length decoding unit 501 obtains combinations of RUN and LEVEL by decoding for one block and writing of the LEVEL is completed, the read control unit 504 controls reading based on a result of determination as to data stored in the information register 509 according to a control signal indicating a read permission sent from the subsequent process unit 506. Specifically, the read control unit 504 outputs an address corresponding to a bit where “1” is stored in the information register 509 to the data buffer 508 and reads out LEVEL located at the address. On the other hand, when the read control unit 504 determines data stored in the information register 509, the data selecting unit 505 outputs, to the subsequent process unit 506, a zero value when it is determined that a bit of the information register 509 stores a zero value, and outputs output data LEVEL read from the data buffer 508 when it is determined that a bit of the information register 509 stores a value of “1”. The subsequent process unit 506 performs a subsequent process on the data received from the data selecting unit 505 via the data selecting unit 505 and outputs the processed data through the output unit 507.

In the conventional technique, the data selecting unit 505 is provided for the step downstream of the data buffer 508, and the data buffer 508 stores not a zero value but only the LEVEL. With this, zero values are selected by the data selecting unit 505 in the downstream. The variable-length decoding unit 501 is thus allowed to continue its operation, which is convenient for faster processing. In addition, the technique allows reduction in accesses to the data buffer 508 by reading only LEVEL based on information on addresses in a address holding unit in a minimum configuration, and therefore a low-power consumption variable-length decoding unit is achieved.

On the other hand, according to the H.264/AVC standard, which is one of the video coding standards, TotalCoeff, level, total_zeros, and run_before are coded. The TotalCoeff indicates the number of nonzero coefficients in a block. The level indicates the magnitude of a nonzero coefficient. The total_zeros indicates the number of zero coefficients preceding the last level in a data scanning direction. The run_before indicates the number of consecutive zero coefficients preceding the last level in the data scanning direction. The RUN and the LEVEL are not coded in combination. The H.264 standard is described in detail in Hyojun Kyokasho H.264/AVC Kyokasho published by Impress, Inc.

FIG. 23 shows a run-length code decode circuit which supports the H.264/AVC standard disclosed in Japanese Unexamined Patent Application Publication Number 2007-329903 (Patent Reference 2). As in the case of Patent Reference 1, the invention disclosed in Patent Reference 2 has an object of reducing accesses to a data buffer to write and read zero values, by determining data buffer addresses of nonzero values using TotalCoeff, total_zeros, and run_before.

The present invention has an object of improving efficiency of variable-length decoding for a plurality of coding standards. In the method according to the present invention, a data buffer for storing nonzero values is used more efficiently, and an information register for determination as to zero value and nonzero value is efficiently used in addition to the data buffer.

### SUMMARY OF THE INVENTION

Patent Reference 1 and Patent Reference 2 mentioned above share two problems. One problem is that data located at a data buffer address corresponding to a zero value may be invalid because the address adding unit 502 determines a write location of a nonzero coefficient in the data buffer 508. The other problem is that the number of consecutive zero values among coefficients after orthogonal transformation increases as the frequency of components increases. As a result, the information register 509 also has an area where the value of “0” is registered in series. When it is known that an area of an information register is filled with “0”, registering “0” in the area to the full is a redundant operation. In addition, consuming an area of the information register, which is a limited resource, by filling the area with “0” is inefficient.

For example, in recent years, semiconductor circuits have been required to perform complex and various video coding processes and high-resolution video processes. Furthermore, reduction in power consumption is also required in terms of environmental measures. However, reducing accesses for writing and reading of nonzero coefficients and improving efficiency of processes still fail to achieve sufficient reduction in power consumption or increase in efficiency.

In order to solve the problems, the present invention has an object of providing a variable-length decoding device which more efficiently uses an information register in addition to a data buffer in which nonzero coefficients are stored, and consumes less power.

A variable-length decoding device, which solves the problems according to an aspect of the present invention, decodes coded data including a variable-length code into component values composing a block, the device including: a variable-length decoding unit configured to decode the coded data into the component values; a data determination unit configured to determine whether or not each of the decoded component values is a specific value; a data buffer that holds only a component value which is determined, by the data determination unit, as not being the specific value from among the decoded component values; an end determination unit configured to determine whether or not each of the decoded component values in a block is a last component value among the component values each determined as not being the specific value in the block; a flag buffer which holds flags each of which has a corresponding component value among the component values from the component value at a beginning of the block to the component value determined as being the last component value by the end determination unit, each of the flags indicating whether or not the corresponding component value is the specific value; a flag buffer control unit configured to (i) set, as the flags in the flag buffer, results of the determination by the data determination unit for the component values from the component value at the beginning of the block to the component value determined as being the last component value by the end determination unit, and (ii) hold an end address which is a data buffer address corresponding to the component value determined as being the last component value; a data buffer control unit configured to perform, based on the flags set in the flag buffer, (i) control such that only the component value determined as not being the specific value by the data determination unit is written in the data buffer and (ii) control such that only the component value determined as not being the specific value is read from the data buffer; and a selecting unit configured to select either zero or the component value read from the data buffer, wherein the flag buffer control unit is configured to control the selection by the selecting unit, based on the flags stored in the flag buffer and the end address.

In this configuration, the number of the flags held in the flag buffer (which corresponds to the information register in the conventional techniques) is not the same as the number of all the component values (coefficients) in a block but the same as the number of component values from the component value at the beginning of the block to the last component value in the block which is not the specific value. Thus, the flag buffer does not hold flags for the component values following the last component value. This reduces the size of necessary storage area of the flag buffer and the data buffer for each block, so that the flag buffer and the data buffer can be used with increased efficiency.

There are usually consecutive zero component values at the end of a block. In this configuration, the space for holding flags as many as such consecutive zero component values at the end of the block can be saved, so that the flag buffer and the data buffer can be used with increased efficiency.

In addition, this reduces the number of writing operations and component value reading operations by the number of the consecutive zero component values at the end of the block, and therefore power consumption is reduced.

Here, the specific value may be zero, the variable-length decoding unit may be further configured to detect at least one of a first parameter and a second parameter from the coded data, the first parameter may be an EOB code indicating that each of the component values following the first parameter in a block is the last component value, a second parameter may include a first code and a second code, the first code indicating the number of component values which are included in the block and are not equal to the specific value, and the second code indicating the number of component values which are included in the block precedes the last component value, and is equal to the specific value, and the end determination unit may be configured to determine whether or not each of the decoded component values is the last component value, based on at least one of the first parameter and the second parameter detected by the variable-length decoding unit. In this configuration, the end determination unit detects the last component value based on the first parameter (the EOB code) or the second parameter included in the coded data, so that the variable-length decoding device can handle a variety of coded data coded in conformity with different standards.

Here, the variable-length decoding device may further include a determination data storage unit configured to record a given determination data set externally and provide the determination data to the data determination unit as the specific value. In this configuration, the specific value (determination data) may be set as necessary. For example, the specific value is typically “0”, but may be a code indicating “0”, a value other than “0”, or a code indicating a value other than “0”.

Here, the determination data set in the determination data storage unit may indicate a zero value when a coding standard of the coded data is one of MPEG-2, H.264, and VC-1.

Here, each of the flags set in the flag buffer may be “0” when the data determination unit determines that the corresponding component value of the flag is the specific value, and be “1” when the data determination unit determines that the corresponding component value of the flag is a value other than the specific value. The flag of “0” corresponds to a component value which is in a block at a high rate. Therefore, in this configuration, the process of setting “0” is saved by zero-clearing the flag buffer, so that power consumption is further reduced. The data buffer control unit performs control of writing to and reading from the data buffer only when the flag is “1”, so that the writing to and reading from the data buffer can be easily controlled using flags.

Here, in the case where a coding standard of the coded data is one of MPEG-2, H.264, and VC-1, each of the flags set in the flag buffer may be “0” when the data determination unit determines that the corresponding component value of the flag is zero, and be “1” when the data determination unit determines that the corresponding component value of the flag is a value other than zero.

Here, the flag buffer control unit may be further configured to set a flag following the flag corresponding to the last component value to “0” in the flag buffer. In this configuration, a one-bit flag is representative of flags each of which corresponds to one of consecutive zero coefficients following the last component value to the end of the block (flags at the end of a block in the conventional techniques), so that the number of bits of flags are explicitly reduced.

Here, the end determination unit may be configured to select one of the first parameter and the second parameter for use in the determination as to whether or not each of the component values is the last component value.

Here, the end determination unit may be configured to select the first parameter when a coding standard of the coded data is one of MPEG and VC-1 and select the second parameter when the coding standard of the coded data is H.264 In this configuration, operations by the end determination unit may be switched depending on the types of coded data (the standard to which the coded data conforms).

Here, the end determination unit may be configured to issue a request to the flag buffer control unit for stop of writing, when the end determination unit determines that one of the decoded component values is the last component value, and the flag buffer control unit may be configured to stop setting a flag in the flag buffer when the flag buffer control unit receives the request for stop of writing from the end determination unit. In this configuration, the process of stopping setting of flags for the component values following the last component value is promptly stopped.

Here, the end determination unit may be further configured to issue a request to the flag buffer control unit for stop of updating, when the number of components output from the selecting unit reaches the number of component values from the component value at the beginning of the block up to the last component value in the block, and the flag buffer control unit may be configured to stop updating a flag buffer read pointer of the flag buffer for reading of the component values following the last component value in the block and output a flag of zero to the data buffer control unit, when the flag buffer control unit receives a request for stop of reading from the end determination unit. In this configuration, after component values are read up to the last component value in a block, a flag of “0” is repeatedly output for the component values from the component value following the last component value up to the component value at the end of the block. This also reduces power consumption in reading data from the flag buffer and the data buffer.

Here, the flag buffer control unit may be configured to initialize an area of the flag buffer to zero before or after decoding coded data corresponding to the block, the area corresponding to a block. In this configuration, the process of setting “0” for each zero component value is saved by zero-clearing the flag buffer in advance, so that power consumption is further reduced.

Here, the variable-length decoding device may further include a free space managing unit configured to manage free space in the data buffer and free space in the flag buffer, and issue a request to the variable-length decoding unit for stop of decoding or a permission to the variable-length decoding unit to decode a following block, depending on the free space in the data buffer and the free space in the flag buffer. In this configuration, the flag buffer does not hold flags for component values from the component value following the last component value to the component value at the end of the block, so that free space in the flag buffer and the data buffer for the components values are saved. The free space can be used for the next block for higher efficiency. In addition, variable-length decoding of the following block is moved forward so that performance of processing is increased.

Here, the free space managing unit may be configured to issue the permission to the variable-length decoding unit to decode a following block, when the data buffer and the flag buffer have free space at a time when the end determination unit determines that one of the decoded component values is the last component value. In this configuration, the free space can be used for the next block for higher efficiency. In addition, variable-length decoding of the following block is moved forward so that performance of processing is increased.

Here, the flag buffer has a capacity for holding at least 64 flags.

Here, the data buffer control unit may be configured to initialize an area of the data buffer to zero before or after decoding coded data corresponding to the block, the area corresponding to a block.

Here, the data buffer has an area corresponding to a block which may be capable of holding 64 component values.

Here, the free space managing unit may be configured to issue a request to the variable-length decoding unit for stop of decoding when at least one of the data buffer and the flag buffer has no free space.

Furthermore, a variable-length decoding device according to another aspect of the present invention decodes coded data including a variable-length code into component values composing a block, the device including: a variable-length decoding unit configured to detect and decode a first code, a second code, a third code, and a fourth code from the coded data, the first code being TotalCoeff which indicates the number of nonzero coefficients included in a block, the second code being totalzero which indicates the number of zero coefficients preceding a last nonzero coefficient in the block, the third code being LEVEL which indicates a value of a nonzero coefficient, and the fourth code being run_before which indicates the number of consecutive zero coefficients preceding the LEVEL; an end determination unit configured to determine a last coefficient among nonzero coefficients in the block, based on the first code and the second code; a flag buffer which holds flags each of which has a corresponding coefficient among coefficients from a coefficient at a beginning of the block to a coefficient determined as being the last nonzero coefficient by the end determination unit, each of the flags indicating whether the corresponding coefficient is a zero coefficient or a nonzero coefficient; a data buffer which holds only a nonzero coefficient among decoded coefficients; a flag buffer control unit configured to set the flags in the flag buffer based on the decoded first code to the fourth code and hold an end address, each of the flags indicating whether the corresponding coefficient among the coefficients from the coefficient at the beginning of the block to the last nonzero coefficient in the block is a zero coefficient or a nonzero coefficient, and the end address being a data buffer address corresponding to the last nonzero coefficient; a data buffer control unit configured to perform, based on the flags set in the flag buffer, (i) control such that only the nonzero coefficient is written in the data buffer, and (ii) control such that the nonzero coefficient is read from the data buffer; and a selecting unit configured to select either zero or the coefficient read from the data buffer, wherein the flag buffer control unit is configured to control the selection by the selecting unit, based on the flags stored in the flag buffer and the end address.

Furthermore, a variable-length decoding device according to another aspect of the present invention decodes coded data including a variable-length code into component values composing a block, the device comprising: a variable-length decoding unit configured to detect and decode EOB, LEVEL, and RUN, the EOB being a code which indicates a last nonzero coefficient among nonzero coefficients included in a block, the LEVEL being a code which indicates a value of nonzero coefficient, and the RUN being a code which indicates the number of consecutive zero coefficients preceding a nonzero coefficient; an end determination unit configured to determine a last coefficient among nonzero coefficients in the block, based on the EOB; a flag buffer which holds flags each of which has a corresponding coefficient among coefficients from a coefficient at a beginning of the block to a coefficient determined as being the last nonzero coefficient by the end determination unit, each of the flags indicating whether the corresponding coefficient is a zero coefficient or a nonzero coefficient; a data buffer which holds only a nonzero coefficient among decoded coefficients; a flag buffer control unit configured to set the flags in the flag buffer based on the LEVEL and the RUN and hold an end address, each of the flags indicating whether the corresponding coefficient among the coefficients from the coefficient at the beginning of the block to the last nonzero coefficient in the block is a zero coefficient or a nonzero coefficient, and the end address being a data buffer address corresponding to the last nonzero coefficient; a data buffer control unit configured to perform, based on the flags set in the flag buffer, control such that only the nonzero coefficient is written in the data buffer, and control such that the nonzero coefficient is read from the data buffer; and a selecting unit configured to select either zero or the coefficients read from the data buffer, wherein the flag buffer control unit is configured to control the selection by the selecting unit, based on the flags stored in the flag buffer and the end address.

Use of the variable-length decoding device according to the present invention requires less storage area of a flag buffer and a data buffer for a block, so that the flag buffer and the data buffer can be efficiently used. In addition, the count of processes of writing and reading of flags is reduced, so that power consumption is reduced. Furthermore, performance of variable-length decoding is increased.

### FURTHER INFORMATION ABOUT TECHNICAL BACKGROUND TO THIS APPLICATION

The disclosure of Japanese Patent Application No. 2009-040034 filed on Feb. 23, 2009 including specification, drawings and claims is incorporated herein by reference in its entirety.

The disclosure of PCT application No. PCT/JP2009/003542 filed on Jul. 28, 2009, including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 shows a configuration of a variable-length decoding device according to Embodiment 1 of the present invention;

FIG. 2A shows an example of coefficients and an array thereof in a block in an MPEG-2 format;

FIG. 2B shows an example of addresses each corresponding to one of coefficients in a block in an MPEG-2 format;

FIG. 3 shows an information register according to conventional techniques and an example of data stored in a data buffer and a flag buffer according to Embodiment 1;

FIG. 4A shows a relationship between FWP and FRP which are addresses on the flag buffer;

FIG. 4B shows an exemplary circuit which controls suspension and resumption of update of FRP;

FIG. 5 shows exemplary data in the flag buffer in the case where processing of the following block is brought forward by utilizing free space of the flag buffer;

FIG. 6 shows exemplary data in the flag buffer in the case where decoding is performed in units of macroblocks.

FIG. 7 shows exemplary data in the flag buffer in the case where decoding of macroblocks in the next generations is brought forward;

FIG. 8 shows a configuration of a variable-length decoding device according to Embodiment 3 of the present invention;

FIG. 9 shows an exemplary block composed of 4×4 coefficients;

FIG. 10 shows exemplary data items of the 4×4 block are arranged in the reverse order of a zigzag scanning;

FIG. 11 shows an exemplary result of decoding;

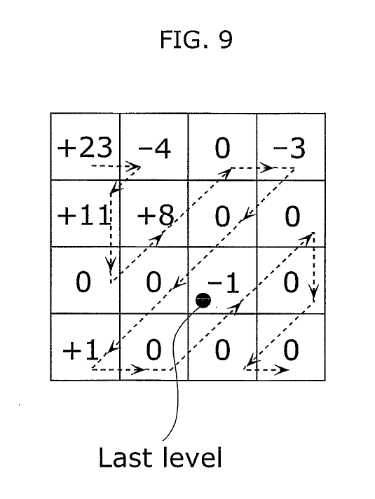

FIG. 9 illustrates decoding of a 4×4 block;

FIG. 13A shows a flag buffer, FWP and FRP in the decoding of a 4×4 block;

FIG. 13B shows an exemplary circuit which controls suspension and resumption of update of FWP;

FIG. 14 illustrates a block composed of 8×8 coefficients;

FIG. 15 shows a configuration of a variable-length decoding device according to Embodiment 5 of the present invention;

FIG. 16 shows a relationship between FWP and FRP which are flag buffer addresses;

FIG. 17 shows a typical process flow of image compression in a conventional technique;

FIG. 18 shows frequency components of an orthogonally transformed block;

FIG. 19 shows zigzag scanning;

FIG. 20 shows a typical process flow of image decoding in a conventional technique;

FIG. 21 shows a configuration of a variable-length decoding unit in the conventional technique;

FIG. 22 shows a run-length code decode circuit in the conventional technique; and

FIG. 23 shows a run-length code decode circuit which supports the H.264/AVC standard in the conventional technique.

### DESCRIPTION OF THE PREFERRED EMBODIMENTS

### Embodiment 1

The following describes Embodiment 1 of the present invention with reference to the drawings.

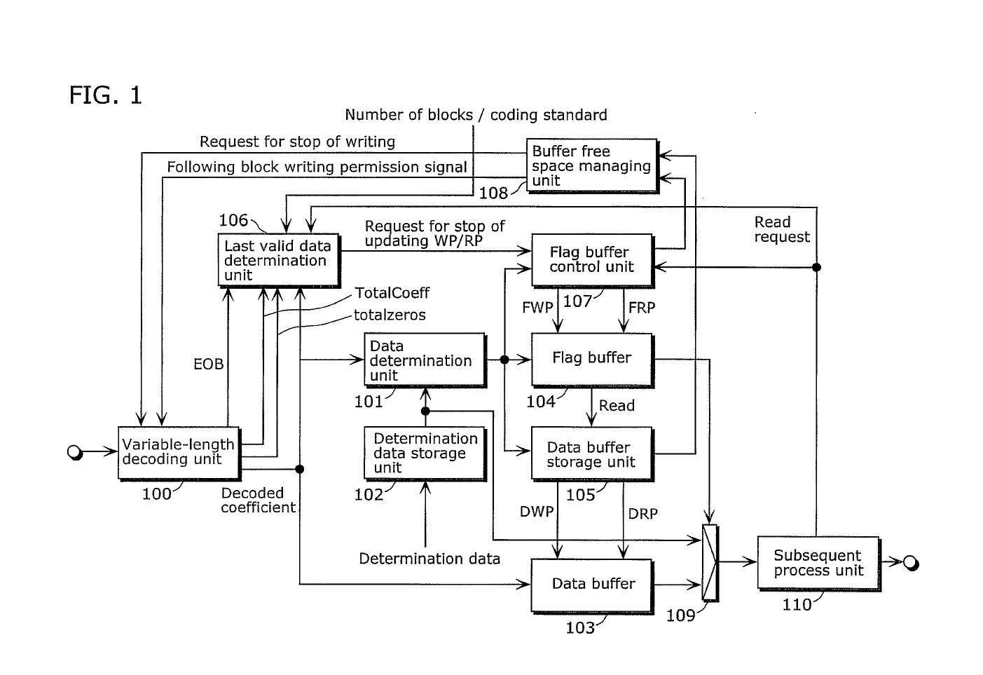

FIG. 1 shows a configuration of a variable-length decoding device according to Embodiment 1 of the present invention. In Embodiment 1, it is assumed that each block is composed of 8×8 coefficients and video data is coded in an MPEG-2 format.

Referring to FIG. 1, the variable-length decoding device includes a variable-length decoding unit 100, a data determination unit 101, a determination data storage unit 102, a data buffer 103, a flag buffer 104, a data buffer control unit 105, a last valid data determination unit 106, a flag buffer control unit 107, a buffer free space managing unit 108, a selecting unit 109, and a subsequent process unit 110.

The variable-length decoding unit 100 decodes coded data into component values (that is, coefficients).

The data determination unit 101 determines whether or not each of the decoded component values is a specific value. The specific value is typically “0” but may be a code indicating “0”, a value other than “0”, or a code indicating a value other than “0”.

The determination data storage unit 102 stores determination data indicating the specific value and outputs the determination data to the data determination unit 101.

The data buffer 103 holds only component values each of which is determined, by the data determination unit 101, as not being the specific value (for example, as being a nonzero coefficient), from among the decoded component values.

The last valid data determination unit 106 determines whether or not each of the decoded component value is the last component value in a block among the component values each determined as not being the specific value in the block. In other words, the last valid data determination unit 106 determines whether or not each of the decoded component values is the last nonzero coefficient in a block.

The flag buffer 104 holds flags each of which has a corresponding component value among the component values from the component value at the beginning of a block to the component value determined as being the last component value by the last valid data determination unit 106 and indicates whether or not the corresponding component value is the specific value. For example, a flag of “0” indicates that the corresponding component value is the specific value (that is, a zero coefficient), and a flag of “1” indicates that the corresponding component value is not the specific value (that is, a nonzero coefficient).

The flag buffer control unit 107 sets, as the flags in the flag buffer, the results of the determination by the data determination unit 101 for the component values from the component value at the beginning of a block to the component value determined as being the last one by the last valid data determination unit 106. Furthermore, the flag buffer control unit 107 may set a flag following the flag corresponding to the last component value to “0”. The flag of “0” is a one-bit flag set as a representative one of the flags for the zero coefficients following the last component value and are consecutive up to the end of the block. The flag buffer control unit 107 includes two registers: one holds a flag buffer write pointer FWP, which is an address for writing a flag in the flag buffer 104; and the other holds a flag buffer read pointer FRP, which is an address for reading out a flag from the flag buffer 104. The flag buffer control unit 107 further includes a register which holds an end address. The end address is an address of a location on the data buffer, corresponding to the component value determined as being the last component value. In addition, the flag buffer control unit 107 controls selection by the selecting unit 109, based on the flag held in the flag buffer 104 and the end address.

The data buffer control unit 105 controls writing of the component value in the data buffer 103 and reading of a component value from the data buffer 103, based on the flags set in the flag buffer 104. The component values to be written in the data buffer 103 and the component values to be read from the data buffer 103 are only the component values each determined as not being the specific value by the data determination unit 101. The data buffer control unit 105 includes two registers for the control: one register holds a data buffer write pointer DWP, which is an address for writing a component value determined as not being the specific value (that is, a nonzero coefficient) in the data buffer 103; and the other holds a data buffer read pointer DRP, which is an address for reading out a nonzero coefficient from the data buffer 103.

The buffer free space managing unit 108 performs space management of the flag buffer 104 and the data buffer 103.

The selecting unit 109 selects either the component values read from the data buffer 103 or the determination data (for example, zero) stored in the determination data storage unit 102, and outputs the result of the selection in response to a read request from the subsequent process unit 110.

The subsequent process unit 110 performs a subsequent process on the decoded coefficients received from the selecting unit 109.

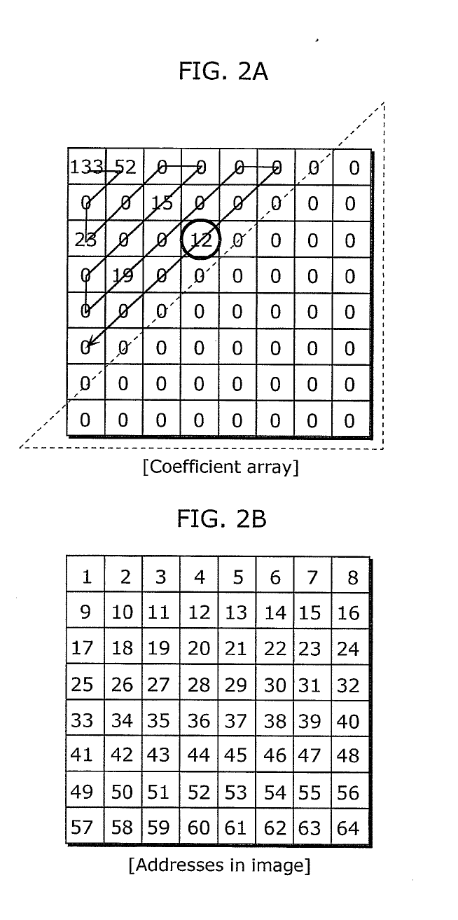

First, upon receiving coded data, the variable-length decoding unit 100 variable-length decodes the coded data, and then outputs coefficients obtained by the decoding to the data determination unit 101 in the zigzag scanning order as shown in FIG. 19. Here, many of the output coefficients have a zero value because the video signal is transformed to a frequency domain by the orthogonal transformation unit as described above. FIG. 2A shows an example of coefficients and an array thereof in a block in an MPEG-2 format. FIG. 2B shows an example of addresses each corresponding to one of the coefficients in a block in an MPEG-2 format. In FIG. 2A, all the coefficients following the circled coefficient having a value of 12 have a zero value.

For the characteristics, a zero value is set in the determination data storage unit 102. The component values output to the data determination unit 101 (that is, the decoded coefficients, hereinafter simply referred to as coefficients) are sequentially compared with the zero value for the determination by the data determination unit 101, and the flag buffer 104 is notified of the results of the determination. When a result is equal to the set value, that is, when the coefficient proves to be a zero value, “0” is stored in the flag buffer. When the coefficient proves to be a zero value, “1” is stored in the flag buffer.

When the value stored in the flag buffer is “1”, the flag buffer notifies the data buffer control unit 105 of update of a data buffer write pointer (hereinafter referred to as DWP) in the data buffer 103, and the corresponding nonzero value is stored in the data buffer. Thus, only nonzero values are registered in the data buffer through this operation.

The above process is performed in blocks each composed of 64 coefficients arranged in an 8×8 matrix. In the MPEG-2 coding standard, additional information is provided which indicates that coefficients following a coefficient among the 64 coefficients are all zero as shown in FIG. 2A and FIG. 2B. The information is called EOB (End Of Block). When the EOB is detected in the process of variable-length coding, the EOB is output to the last valid data determination unit. The last valid data determination unit performs control based on the EOB such that the flag buffer control unit holds the value of the DWP and stops update of the DWP.

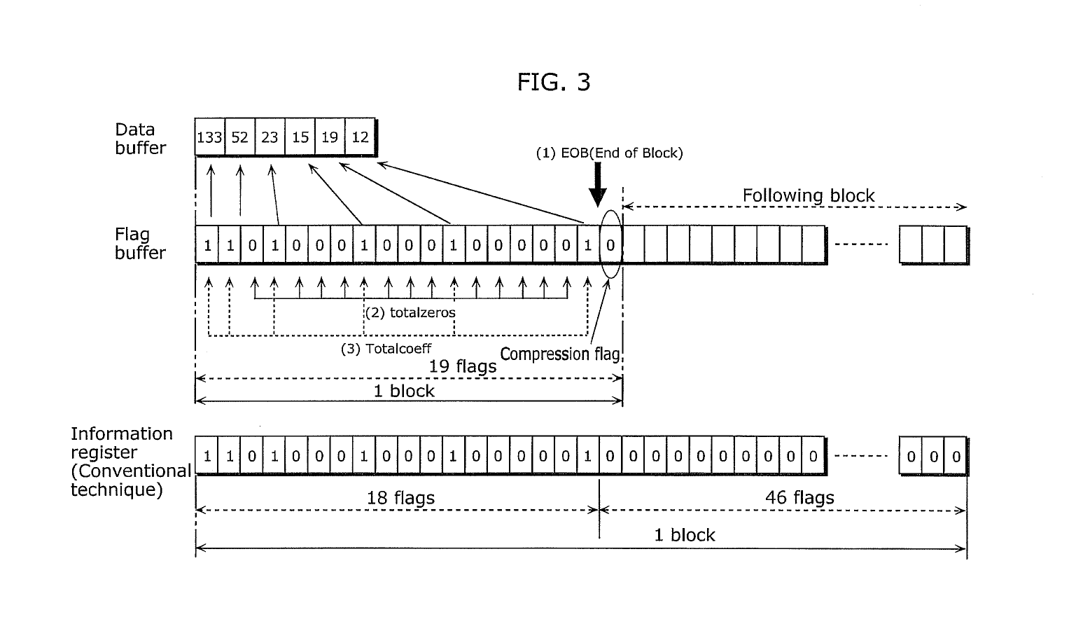

FIG. 3 shows an example of data stored in the data buffer and the flag buffer. The data corresponds to the block shown in FIG. 2A. FIG. 3 also shows exemplary data in an information register in a conventional technique. As shown in FIG. 3, the data buffer 103 stores only nonzero coefficients. The flag buffer 104 holds flags each corresponding to one of coefficients from the coefficient at the beginning of the block to the coefficient determined as being the last nonzero coefficient by the last valid data determination unit 106 (the coefficient having a value of 12 in FIG. 3). Each of the flags indicates whether the corresponding coefficient is a zero coefficient or a nonzero coefficient. In FIG. 3, the flag of “1” indicates that the corresponding coefficient is a nonzero coefficient, and the flag of “0” indicates that the corresponding coefficient is a zero coefficient. In addition, the flag buffer 104 holds a flag of “0” as a flag following the flag corresponding to the last nonzero coefficient. The flag of “0” following the flag corresponding to the last nonzero coefficient is the flag representative of 46 trailing flags. In other words, the 46 flags are compressed into the one flag.

In the conventional techniques, the space in a flag buffer is necessarily consumed by all 64 flags for a block. The control according to Embodiment 1 thus allows reduction in the space in the flag buffer to be consumed so that the flag buffer holds flags only up to the flag for which EOB is detected. Then, the data buffer stores only nonzero coefficients up to the coefficient for which EOB is detected.

Next, the coefficients registered in the data buffer are output to the subsequent process unit. When the subsequent process unit issues a read request to the flag buffer control unit, the flag buffer control unit notifies the flag buffer of update of a flag buffer read pointer (hereinafter referred to as FRP). Then, when the flag at a location in the flag buffer indicated by the FRP is “0”, the flag buffer control unit requests the data buffer control unit to stop update of the data buffer read pointer (hereinafter referred to as DRP), outputs a zero value stored in the determination data storage unit, and switches output data of the selecting unit to the output provided from the determination data storage unit, so that the data from the determination data storage unit is delivered to the subsequent process unit. When the flag at a location indicated by the FRP is “1”, the flag buffer control unit causes the data buffer control unit to update the DRP, outputs the coefficient stored in the data buffer, and switches output data of the selecting unit to the output provided from the data buffer, so that the data from the data buffer is delivered to the subsequent process unit.

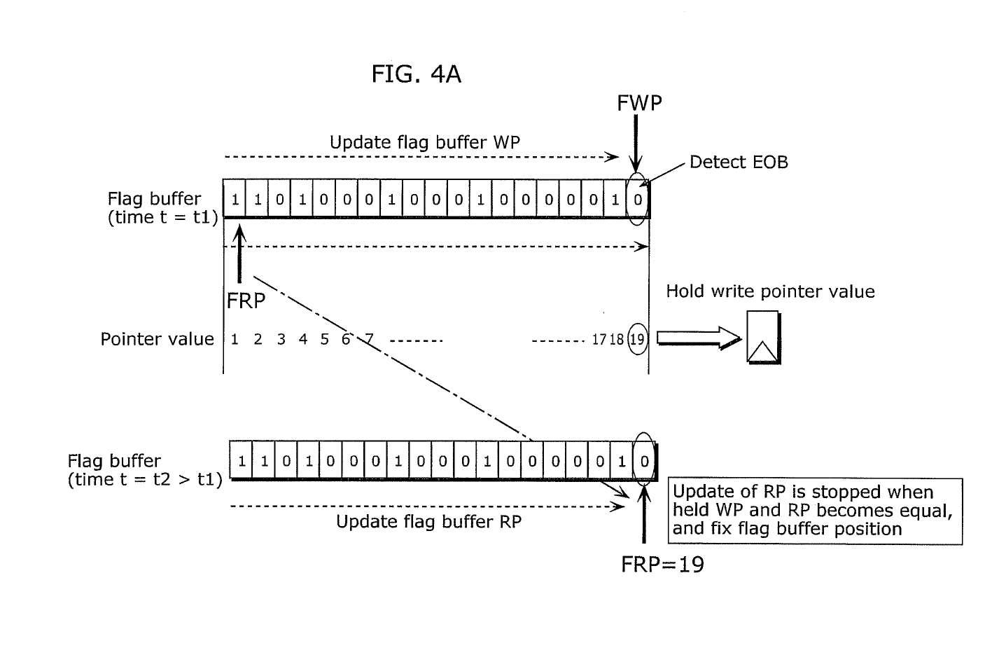

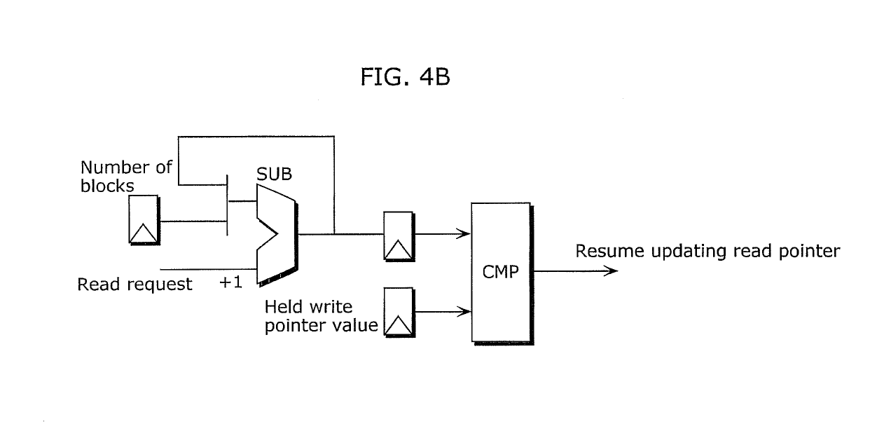

In addition, the read request from the subsequent process unit is input also into the last valid data determination unit so that the last valid data determination unit counts reading. When the comparison shows that the count of reading is equal to the EOB or the FWP, the FRP for the flag buffer is not updated even when a read request is issued from the subsequent process unit, and the FRP refers to the same position. This process is performed using, for example, a circuit as shown in FIG. 4B provided in the last valid data determination unit 106. With this, the part which follows the EOB and for which the WRP of the flag buffer has not been updated can be sequentially read. That is, the trailing zero values after the EOB are compressed to be equivalent to the information indicated by one coefficient registered in the flag buffer, so that consumption of the space in the flag buffer is apparently reduced.

FIG. 4A shows a relationship between the FWP and the FRP, which are addresses on the flag buffer 104. As shown in FIG. 4A, the flag buffer control unit 107 sets flags in the flag buffer 104 while updating the FWP and the FRP. In addition, upon detection of EOB, the flag buffer control unit 107 updates the FWP so that the FWP indicates the address of the flag following the flag corresponding to the last nonzero coefficient, and sets a compressed flag of “0”.

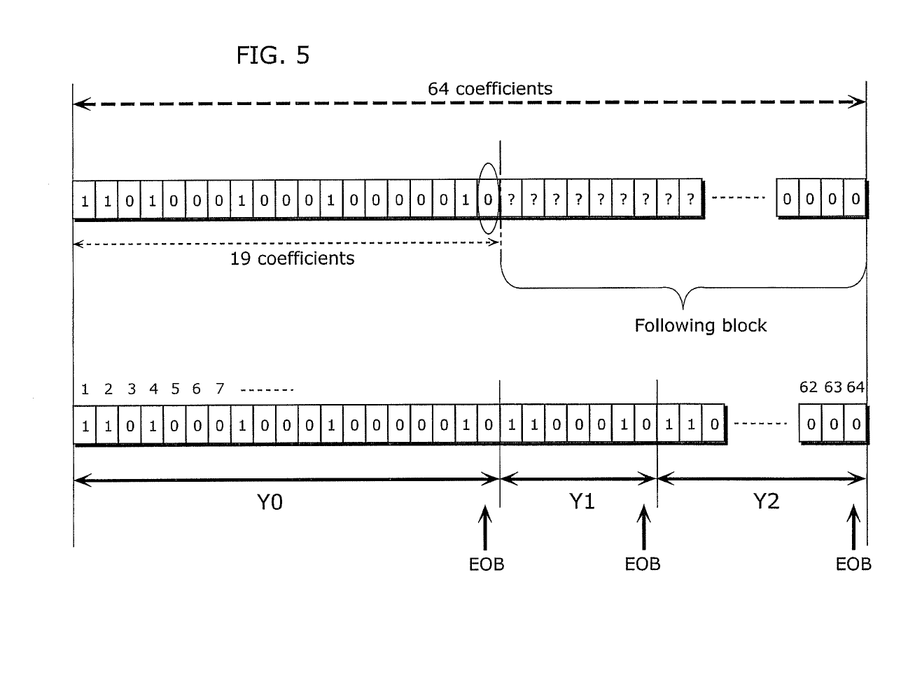

When the coefficients after the EOB are compressed on the flag buffer, the space in the flag buffer, which has been consumed by 64 flags in the conventional techniques, for 64−N flags is left free. Then, the buffer free space managing unit checks the free space in the flag buffer and requests the variable-length decoding unit to decode the following block. In the conventional techniques, processing the following block is not started until the flag buffer stores flags for 64 coefficients. On the other hand, the process according to Embodiment 1 allows moving processing of the following block forward independently of the subsequent process unit, so that the efficiency of variable-length decoding can be increased (see FIG. 5). In this process, the variable-length decoding unit may not output coefficients following the EOB. FIG. 5 shows exemplary data in the flag buffer 104 in the case where processing of the following block is brought forward. The upper row shows exemplary data at the end of decoding of a Y0 block. The lower row shows exemplary data in the case where decoding of a Y1 block following the Y0 block and a Y2 block following them moved forward.

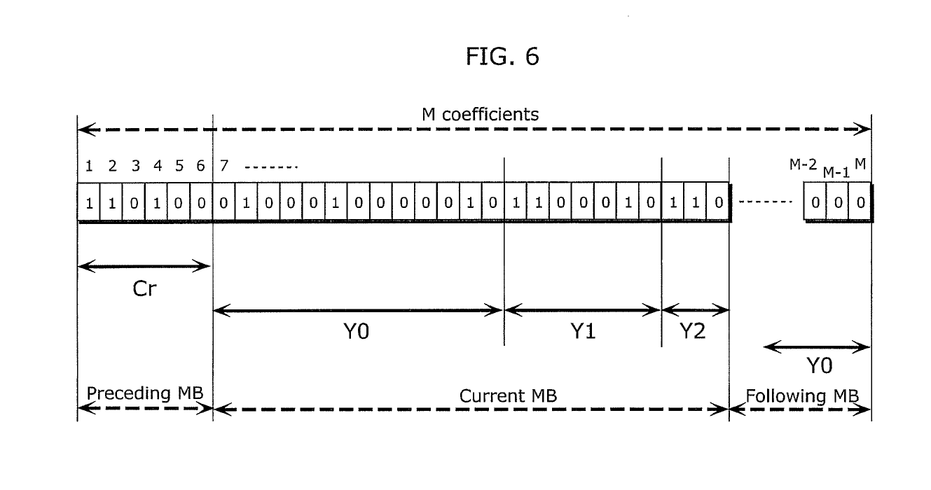

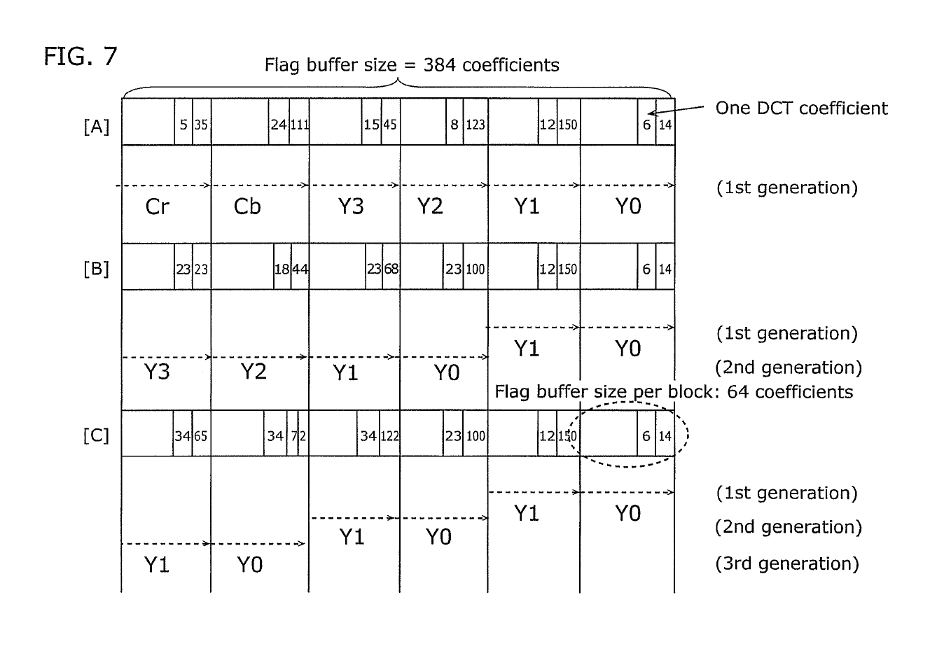

In addition, the above operation is applicable not only to processing a block on a per-block basis but also to processing blocks on a per-macroblock basis (hereinafter referred to as MB) composed of Y0, Y1, Y2, Y3, Cb, and Cr (see FIG. 6 and FIG. 7). A video is composed of groups of MBs. In other words, increase in processing performance in units of MBs is necessary for increase in processing performance for a whole video. In the cases shown in FIG. 6 and FIG. 7, the efficient use of the flag buffer shown in FIG. 5 is expansively applied to processing in units of MBs. In Embodiment 1, variable-length decoding can be moved forward as far as there is an available space in a flag buffer when, for example, there are many blocks or macroblocks including only a few coefficients up to EOB. Therefore, processing performance of variable-length decoding can be increased further.

### Embodiment 2

The following describes Embodiment 2 of the present invention with reference to the drawings. The configuration according to Embodiment 2 of the present invention is shown in FIG. 1, which also shows the configuration according to Embodiment 1 of the present invention, and thus the description thereof is omitted.

A variable-length decoding device according to Embodiment 2 is different from the variable-length decoding device according to Embodiment 1 in that information of which the last valid data determination unit is notified is not EOB but TotalCoeff and totalzeros. In this configuration, as in the case where EOB is used, the number of trailing zero values can be obtained by subtracting the total number of blocks from the sum of TotalCoeff and totalzeros. Therefore, the variable-length decoding device according to Embodiment 2 produces the same effect as the variable-length decoding device according to Embodiment 1.

### Embodiment 3

The following describes Embodiment 3 of the present invention with reference to the drawings.

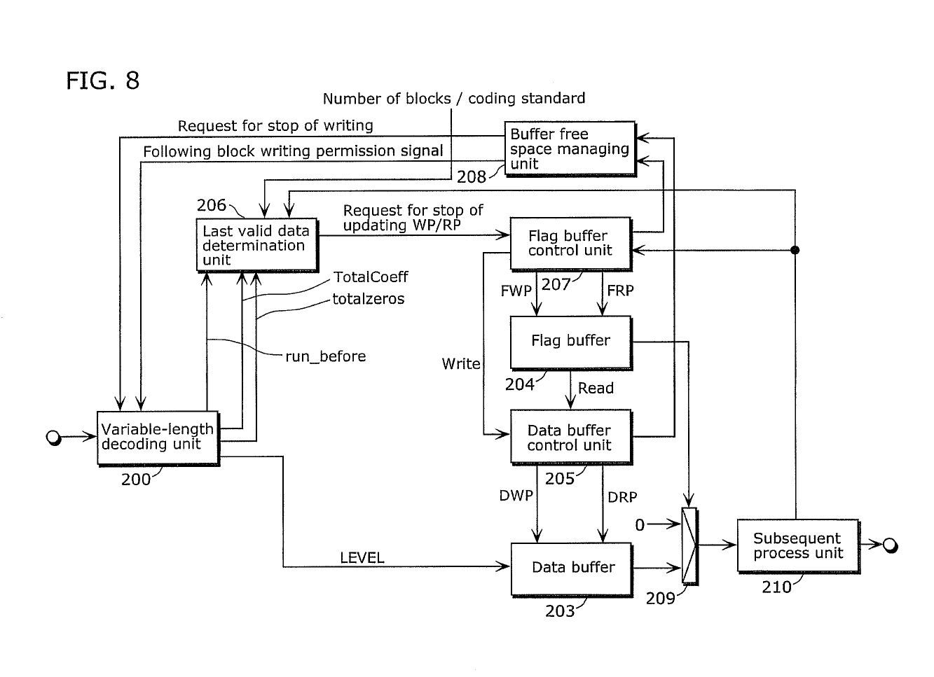

FIG. 8 shows a configuration of a variable-length decoding device according to Embodiment 3 of the present invention. In Embodiment 3, it is assumed that each block is composed of 4×4 coefficients and video data is coded in an H.264/AVC format.

In FIG. 8, the variable-length decoding device includes a variable-length decoding unit 200, a data buffer 203, a flag buffer 204, a data buffer control unit 205, a last valid data determination unit 206, a flag buffer control unit 207, a buffer free space managing unit 208, a selecting unit 209, and a subsequent process unit 210.

The variable-length decoding unit 200 detects and decodes a first code, a second code, a third code, and a fourth code, that is, TotalCoeff, totalzero, LEVEL, and run_before, respectively, from coded data. The TotalCoeff indicates the number of nonzero coefficients included in a block. The totalzero indicates the number of zero coefficients preceding the last nonzero coefficient in a block. The LEVEL indicates the value of a nonzero coefficient. The run_before indicates the number of consecutive zero coefficients preceding LEVEL.

The data buffer 203 holds only nonzero coefficients among the decoded coefficients.

The flag buffer 204 holds flags each having a corresponding coefficient among the coefficients from the coefficient at the beginning of a block to the coefficient determined as being the last nonzero coefficient by the last valid data determination unit 206. Each of the flags indicates whether the corresponding coefficient is a zero coefficient or a nonzero coefficient.

The data buffer control unit 205 controls writing of only nonzero coefficients in the data buffer 203 and reading of nonzero coefficients from the data buffer 203, based on the flag set in the flag buffer 204.

The last valid data determination unit 206 determines the last nonzero coefficient among the nonzero coefficients in a block, based on the first code and the second code. In other words, the last valid data determination unit 206 detects the position of the last nonzero coefficient in a block (a 4×4 block) using TotalCoeff and totalzeros and notifies the flag buffer control unit 207 of the position.

The flag buffer control unit 207 sets flags in the flag buffer 204 based on the first code to the fourth code resulting from the decoding. Each of the flags indicates whether a corresponding one of the coefficients from the coefficient at the beginning of the block to the last nonzero coefficient in the block is nonzero or zero. The flag buffer control unit 207 also holds an end address, which is the data buffer address corresponding to the last nonzero coefficient. In addition, the flag buffer control unit 207 controls selection by the selecting unit 209, based on the flag held in the flag buffer 204 and the end address.

The buffer free space managing unit 208 performs space management of the flag buffer and the data buffer.

The selecting unit 209 selects either the coefficient read from the data buffer 203 or a zero value, and outputs the result of the selection in response to a read request from the subsequent process unit 110.

The subsequent process unit 210 performs a subsequent process on the decoded coefficient received from the selecting unit 209.

First, the variable-length decoding unit 200 sequentially decodes TotalCoeff indicating the number of nonzero coefficients, level indicating the magnitude of a nonzero coefficient, totalzeros indicating the number of zero coefficients preceding the last level in the order of data scanning, and run_before indicating the number of consecutive zero coefficients preceding the level in the order of data scanning.

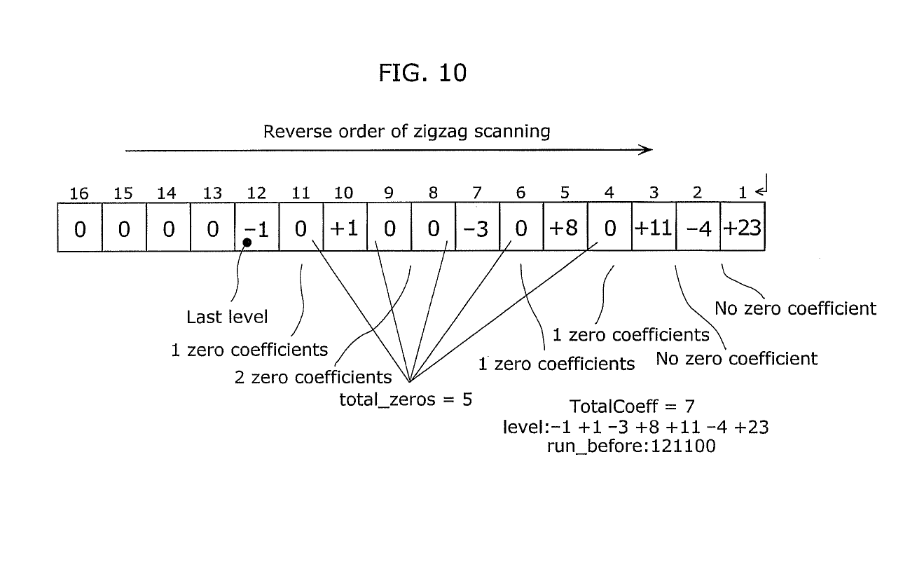

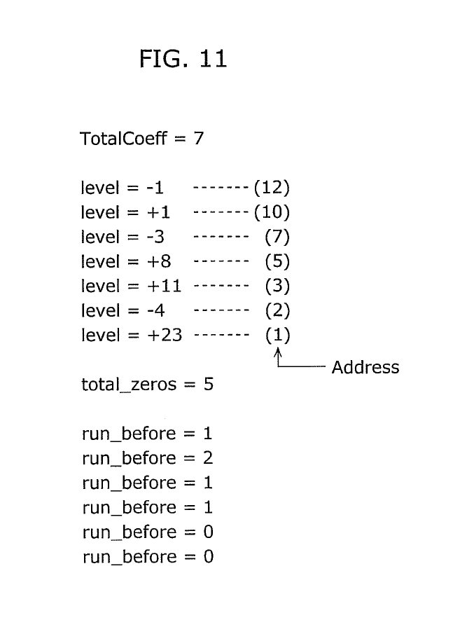

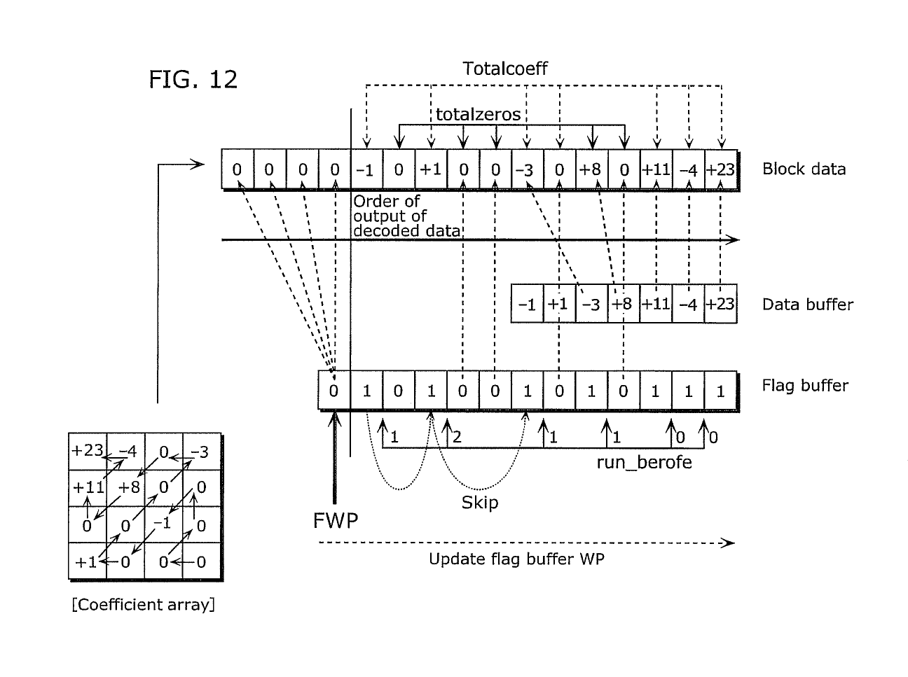

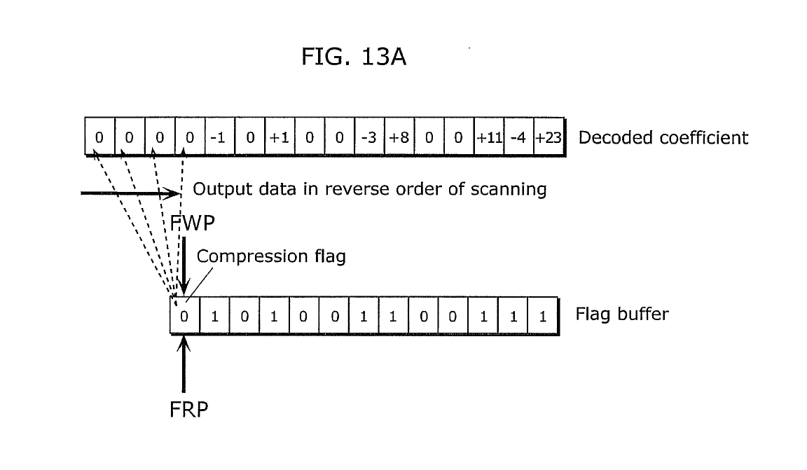

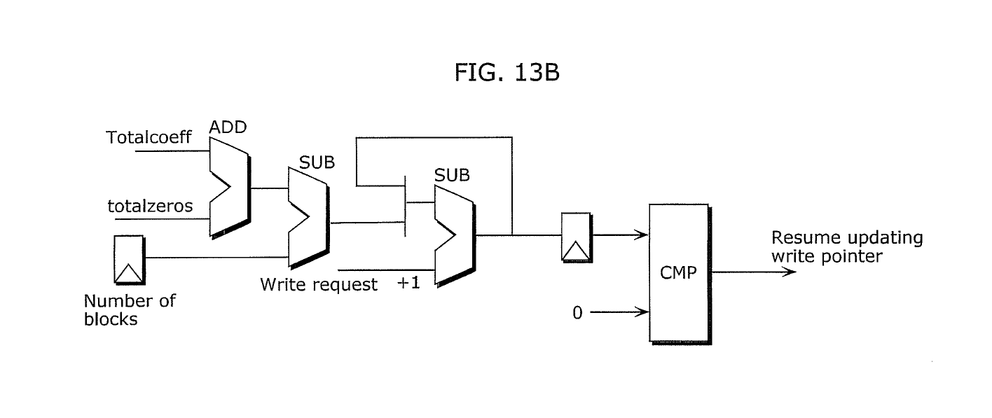

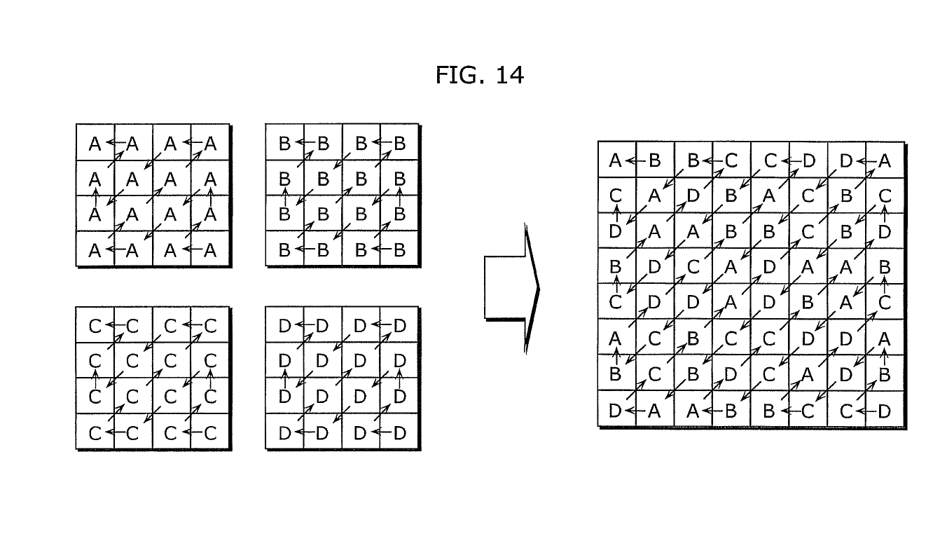

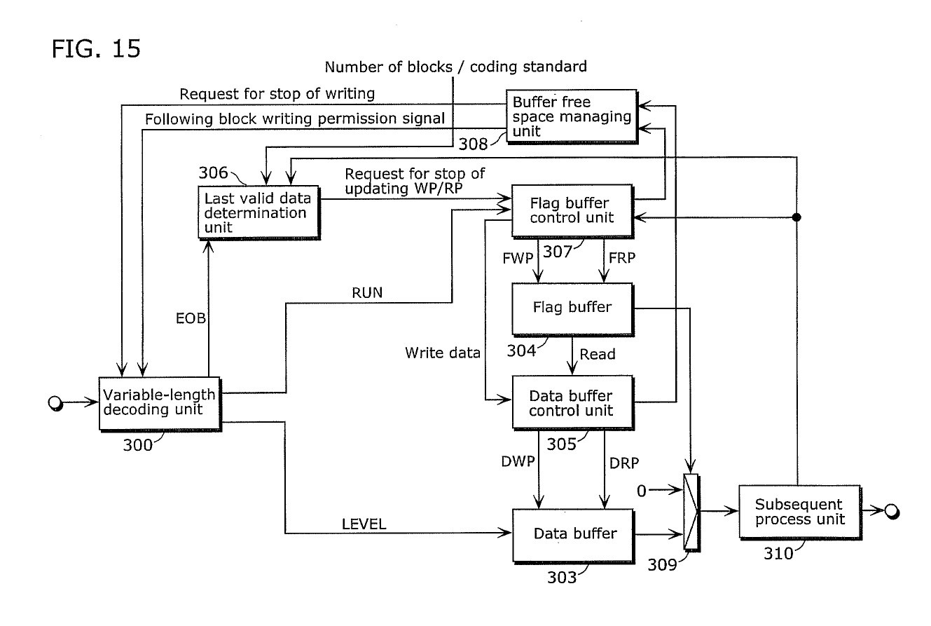

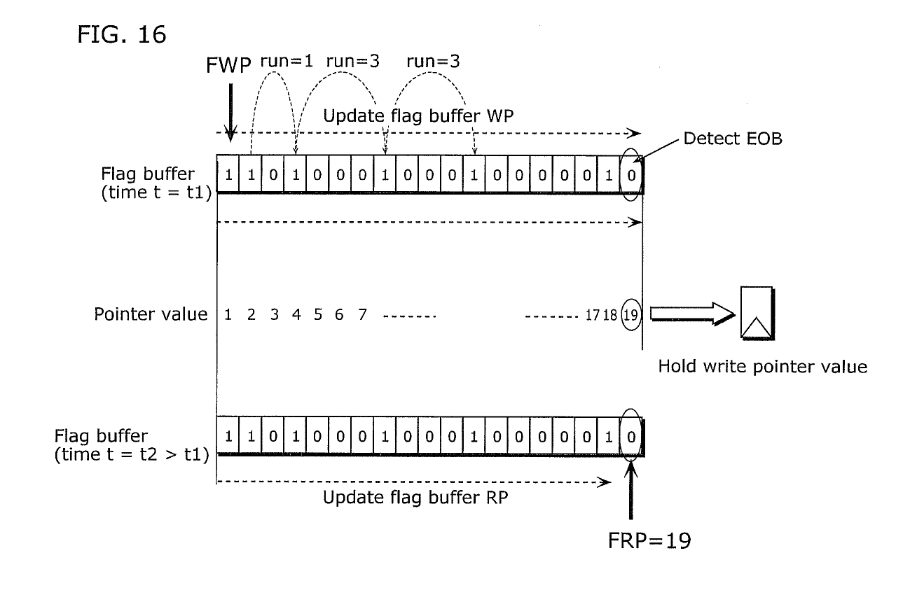

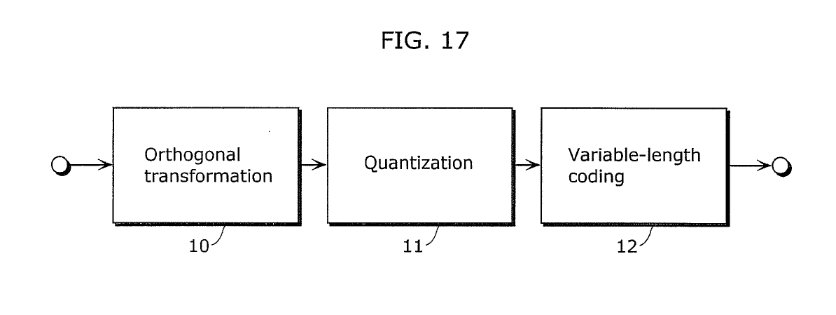

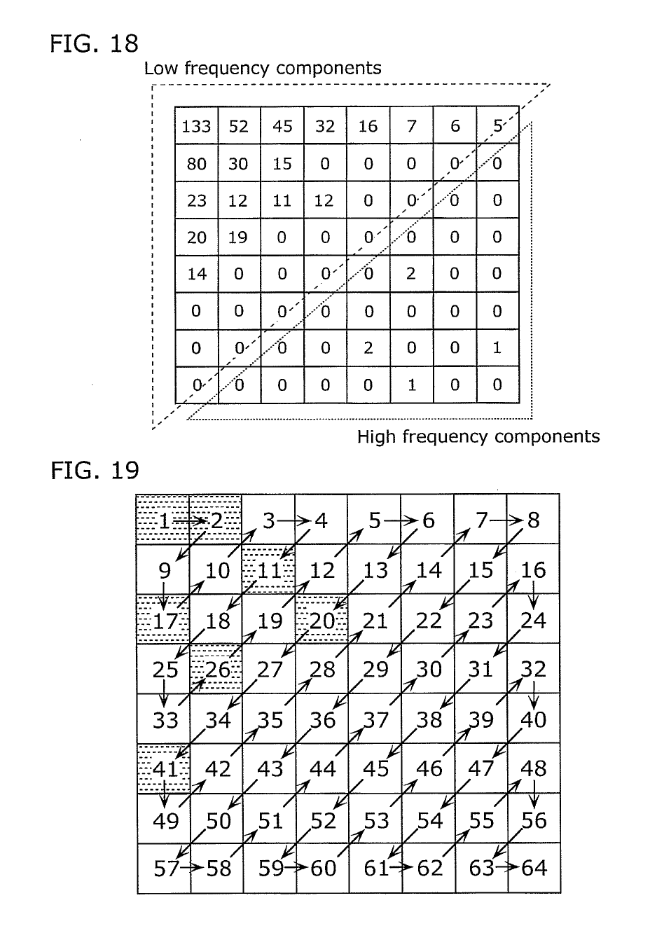

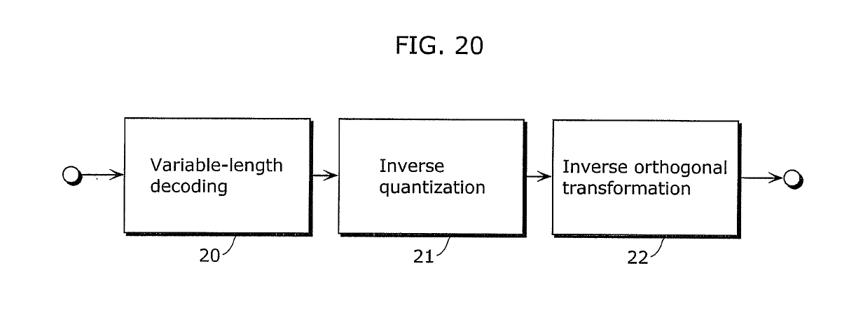

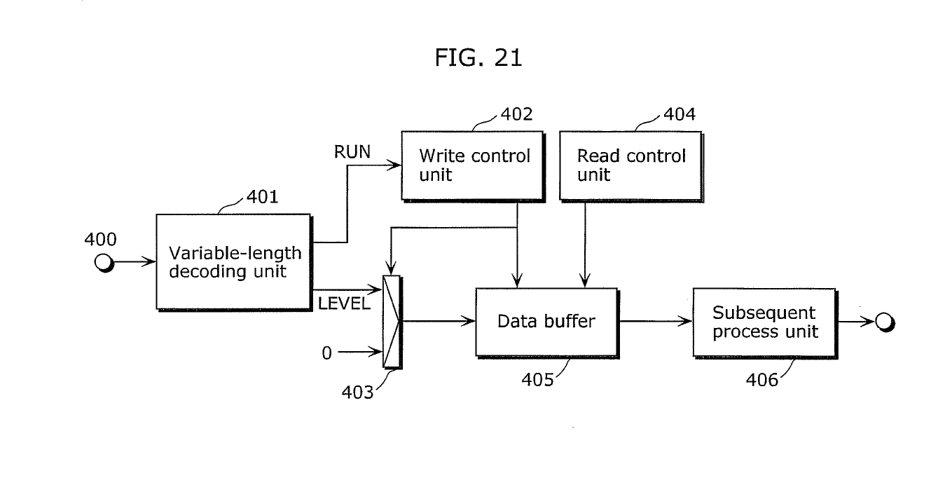

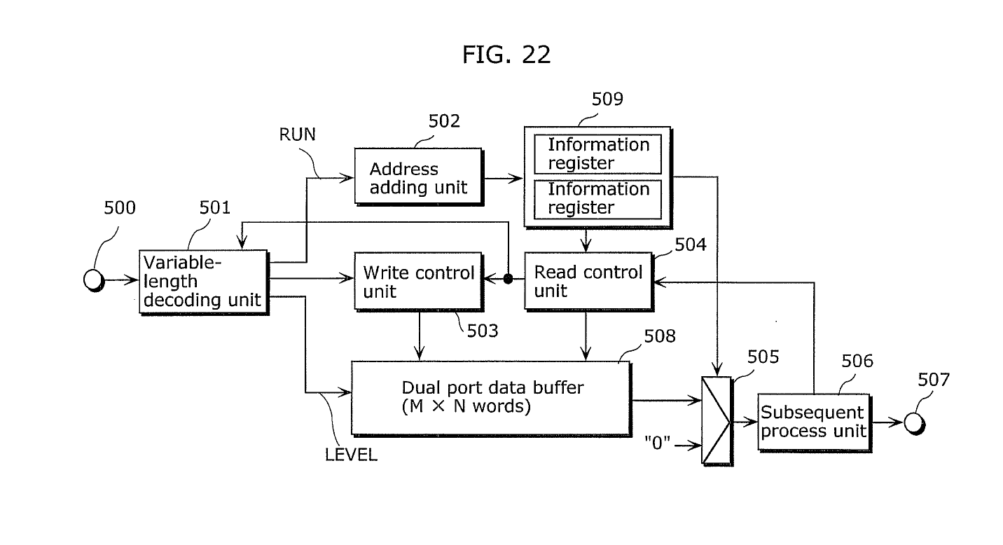

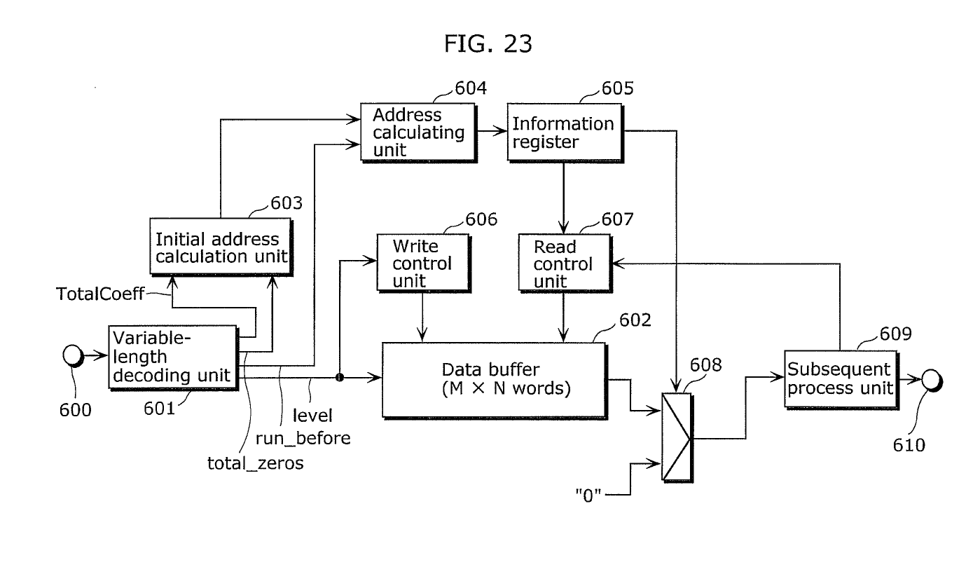

FIG. 9 shows an exemplary result of the decoding. Decoding of data is performed in the reverse order of the zigzag scanning. In FIG. 10, the items of the 4×4 block data shown in FIG. 9 are arranged in the reverse order of the zigzag scanning. FIG. 11 shows an exemplary result of the decoding in the configuration shown in FIG. 8.

In the process of the decoding, firstly, TotalCoeff=7, which indicates the number of the nonzero coefficients (+23, −4, +11, +8, −3, +1, −1) among the 16 coefficients, is obtained. Next, level, each indicating the magnitude of a nonzero coefficient, is obtained in the reverse order of the zigzag scanning, that is, in the order of −1, +1, −3, +8, +11, −4, and +23. Next, totalzeros=5, which indicates the total number of zero values preceding the level=−1 at the end of the zigzag scanning, is obtained. Finally, run_before, which indicates the number of zero values preceding the last level, is decoded in the reverse order of the zigzag scanning, that is, in the order of 1, 2, 1, 1, 0, and 0.

As a result, the numbers of zero values in the data resulting from the decoding are as follows:
the number of zero values preceding level=−1 is 1;
the number of zero values preceding level=+1 is 2;
the number of zero values preceding level=−3 is 1;
the number of zero values preceding level=+8 is 1;
the number of zero values preceding level=+11 is 0 (no zero precedes level=+11);
the number of zero values preceding level=−4 is 0; and
the number of zero values preceding level=+23 is 0.

On the basis of the result, obtained run_before are 1, 2, 1, 1, 0, and 0, in the reverse order of the zigzag scanning.

The following describes a process flow with reference to FIG. 12.

First, the values of level are only nonzero values, and therefore they do not need to be compared with a zero value. The values of level are written in series in the data buffer.

Next, the values of TotalCoeff=7 and totalzeros=5 are obtained in the decoding, and the last valid data determination unit is notified of the two values. The number of components of the block is 16, and therefore the number of consecutive zero values is 16−12=4. In the case of the H.264, data is decoded in the reverse order of the scanning order. Therefore, update of the flag buffer write pointer FWP is suspended for four coefficients.

Because it is already known that the fifth coefficient has a value of level, the flag buffer corresponding to the next FWP is set to “1”. The level corresponding to “1” is the first coefficient 1.

Next, the FWP for the flag buffer is skipped according to the values of run_before (see FIG. 13A and FIG. 13B), and “0” is stored in the location in the flag buffer corresponding to the skipped FWP. Each of the values of the run_before indicates the number of consecutive zero coefficients preceding LEVEL in the data scanning order. That is, FWP following FWP in which “1” is stored is also “1” because FWP is skipped according to the value of run_before.

Thus, use of the last valid data determination unit and the flag buffer control unit allows suspending update of the first FWP and skipping of FWP by the value of run_before, so that consumption of the flag buffer is apparently reduced by four coded coefficients as in Embodiment 1.

Next, in reading of coefficients, the operation is the reverse of the operation according to Embodiment 1. Start of reading is suspended for the four coefficients of the suspension of updating the FWP, which is calculated from TotalCoeff=7 and totalzeros=5, and then coefficients are sequentially read from flag buffer and the data buffer.

In this configuration, the flag buffer and the data buffer can be efficiently used as in Embodiment 1 when H.264/AVC is used as a coding standard, and performance of the variable-length decoding unit can be increased.

### Embodiment 4

The following describes Embodiment 4 of the present invention with reference to the drawings. The configuration according to Embodiment 4 of the present invention is shown in FIG. 2, which also shows the configuration according to Embodiment 3 of the present invention, and thus the description thereof is omitted.

The variable-length decoding device according to Embodiment 4 is different from the variable-length decoding device according to Embodiment 3 in that each block is composed not of 4×4 coefficients but of 8×8 coefficients. In this configuration, a block composed of 8×8 coefficients is processed in variable-length decoding in units of 4×4 pixels, and output to a data buffer in the scanning order as shown in FIG. 14. When a block configuration is thus changed and high-frequency components in a unit of 4×4 pixels have zero values, an 8×8 block including the 4×4 pixels includes many zero values. Therefore, the same effect as in Embodiment 3 is achieved.

### Embodiment 5

The following describes Embodiment 5 of the present invention with reference to the drawings.

FIG. 15 shows a configuration of a variable-length decoding device according to Embodiment 5 of the present invention as claimed in Claim 20. In Embodiment 5, it is assumed that each block is composed of 8×8 coefficients and video data is coded in an MPEG-1 format, an MPEG-2 format, an MPEG-4 format, or a VC-1 format.

Referring to FIG. 15, the variable-length decoding device includes a variable-length decoding unit 300, a data buffer 303, a flag buffer 304, a data buffer control unit 305, a last valid data determination unit 306, a flag buffer control unit 307, a buffer free space managing unit 308, a selecting unit 309, and a subsequent process unit 310.

The variable-length decoding unit 300 detects and decodes EOB, LEVEL, and RUN from coded data. The EOB is a code indicating the last nonzero coefficient among the nonzero coefficients in a block. The LEVEL is a code indicating the value of a nonzero coefficient. The RUN is a code indicating the number of consecutive zero coefficients preceding a nonzero coefficient.

The last valid data determination unit 306 determines the last nonzero coefficient among the nonzero coefficients in a block, based on the EOB.

The data buffer 303 holds only nonzero coefficients among the decoded coefficients.

The flag buffer 304 holds flags each having a corresponding coefficient among the coefficients from the coefficient at the beginning of a block to the coefficient determined as being the last nonzero coefficient by the last valid data determination unit 306. Each of the flags indicates whether the corresponding coefficient is a zero coefficient or a nonzero coefficient.

The flag buffer control unit 307 sets flags in the flag buffer 304 based on the LEVEL and the RUN. Each of the flags indicates whether a corresponding one of the coefficients from the beginning of the block to the last nonzero coefficient in the block is nonzero or zero. The flag buffer control unit 307 also holds an end address, which is the data buffer address corresponding to the last nonzero coefficient. In addition, the flag buffer control unit 307 controls selection by the selecting unit 309, based on the flag held in the flag buffer and the end address.

The data buffer control unit 305 controls writing of only nonzero coefficients in the data buffer 303 and reading of nonzero coefficients from the data buffer 303, based on the flag set in the flag buffer 304.

The buffer free space managing unit 308 performs space management of the flag buffer and the data buffer.

The selecting unit 309 selects either the coefficient read from the data buffer or a zero value.

The subsequent process unit 310 performs a subsequent process on the decoded coefficient received from the selecting unit 309.

The variable-length decoding device according to Embodiment 5 is different from the variable-length decoding device according to Embodiment 1 in that the results of comparison between variable-decoded coefficients and a determination value sequentially made by the variable-length decoding device according to Embodiment 5 are not stored in the flag buffer or the data buffer, and that but the variable-length decoding device updates the flag buffer with consecutive zero values.

The variable-length decoding unit according to Embodiment 5 obtains RUN and LEVEL by decoding. The RUN indicates the number of consecutive zero values. The LEVEL indicates a nonzero value. The flag buffer control unit is notified of the value of RUN such that FWP for the flag buffer is skipped according to the value of the FWP as shown in FIG. 16. The coded coefficients each corresponding to one of the skipped FWP have zero values, so that “0” is stored in the location in the flag buffer corresponding to the skipped FWP. In addition, “1” is written in the location next to the location in the flag buffer corresponding to the skipped FWP, and a LEVEL value corresponding to the flag buffer is stored in the data buffer.

Determination of the last valid data item is performed using EOB as in Embodiment 1. When EOB is detected, FWP and FRP refer to the same location in the flag buffer while zero values are in series, so that consumption of the flag buffer is apparently reduced.

In this configuration, in the case where the limited coding formats are used, the same advantageous effects as the effects of Embodiment 1 are achieved without using the data determination unit and the determination data storage unit.

### Embodiment 6

For Embodiment 6, detailed description is omitted because the technique according to Embodiment 6 is applicable to Embodiment 1 to Embodiment 5 in common. The flag buffers described in all the embodiments above may initialize values stored therein to “0” at the end of reading of each block when the result of determination is equal to the determination value or a zero value or when it is desired to save the process of storing a flag of “0” upon skipping of pointers according to run_before or a RUN value.

In this configuration, the process of storing “0” in the flag buffer is omitted so that performance of variable-length decoding is further increased.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The variable-length decoding device according to the present invention allows reduction in space necessary for variable-length decoding of video according to the standards of MPEG-1, MPEG-2, MPEG-4, H.264/AVC, and VC-1, and increases performance of processing the video. The variable-length decoding device is therefore applicable to image coding such as video coding.

What is claimed is:

1. A variable-length decoding device which decodes coded data including a variable-length code into component values composing a block, said device comprising:
a variable-length decoding unit configured to decode the coded data into the component values;
a data determination unit configured to determine whether or not each of the decoded component values is a specific value;
a data buffer that holds only a component value which is determined, by said data determination unit, as not being the specific value from among the decoded component values;
an end determination unit configured to determine whether or not each of the decoded component values in a block is a last component value among the component values each determined as not being the specific value in the block;
a flag buffer which holds flags each of which has a corresponding component value among the component values from the component value at a beginning of the block to the component value determined as being the last component value by said end determination unit, each of the flags indicating whether or not the corresponding component value is the specific value;
a flag buffer control unit configured to (i) set, as the flags in said flag buffer, results of the determination by said data determination unit for the component values from the component value at the beginning of the block to the component value determined as being the last component value by said end determination unit, and (ii) hold an end address which is a data buffer address corresponding to the component value determined as being the last component value;
a data buffer control unit configured to perform, based on the flags set in said flag buffer, (i) control such that only the component value determined as not being the specific value by said data determination unit is written in said data buffer and (ii) control such that only the component value determined as not being the specific value is read from said data buffer; and
a selecting unit configured to select either zero or the component value read from said data buffer,
wherein said flag buffer control unit is configured to control the selection by said selecting unit, based on the flags stored in said flag buffer and the end address.

2. The variable-length decoding device according to claim 1,
wherein the specific value is zero,
said variable-length decoding unit is further configured to detect at least one of a first parameter and a second parameter from the coded data,
the first parameter is an EOB code indicating that each of the component values following the first parameter in a block is the last component value,
a second parameter includes a first code and a second code, the first code indicating the number of component values which are included in the block and are not equal to the specific value, and the second code indicating the number of component values which are included in the block precedes the last component value, and is equal to the specific value, and
said end determination unit is configured to determine whether or not each of the decoded component values is the last component value, based on at least one of the first parameter and the second parameter detected by said variable-length decoding unit.

3. The variable-length decoding device according to claim 1, further comprising
a determination data storage unit configured to record a given determination data set externally, and provide the determination data to said data determination unit as the specific value.

4. The variable-length decoding device according to claim 3,
wherein the determination data set in said determination data storage unit indicates a zero value when a coding standard of the coded data is one of MPEG-2, H.264, and VC-1.

5. The variable-length decoding device according to claim 1,
wherein each of the flags set in said flag buffer is “0” when said data determination unit determines that the corresponding component value of the flag is the specific value, and is “1” when said data determination unit determines that the corresponding component value of the flag is a value other than the specific value.

6. The variable-length decoding device according to claim 2,
wherein, in the case where a coding standard of the coded data is one of MPEG-2, H.264, and VC-1, each of the flags set in said flag buffer is “0” when said data determination unit determines that the corresponding component value of the flag is zero, and is “1” when said data determination unit determines that the corresponding component value of the flag is a value other than zero.

7. The variable-length decoding device according to claim 6,
wherein said flag buffer control unit is further configured to set a flag following the flag corresponding to the last component value to “0” in said flag buffer.

8. The variable-length decoding device according to claim 2,
wherein said end determination unit is configured to select one of the first parameter and the second parameter for use in the determination as to whether or not each of the component values is the last component value.

9. The variable-length decoding device according to claim 8,
wherein said end determination unit is configured to select the first parameter when a coding standard of the coded data is one of MPEG and VC-1 and select the second parameter when the coding standard of the coded data is H.264.

10. The variable-length decoding device according to claim 1,
wherein said end determination unit is configured to issue a request to said flag buffer control unit for stop of writing, when said end determination unit determines that one of the decoded component values is the last component value, and
said flag buffer control unit is configured to stop setting a flag in said flag buffer when said flag buffer control unit receives the request for stop of writing from said end determination unit.

11. The variable-length decoding device according to claim 1,
wherein said end determination unit is further configured to issue a request to said flag buffer control unit for stop of updating, when the number of components output from said selecting unit reaches the number of component values from the component value at the beginning of the block up to the last component value in the block, and
said flag buffer control unit is configured to stop updating a flag buffer read pointer of said flag buffer for reading of the component values following the last component value in the block and output a flag of zero to said data buffer control unit, when said flag buffer control unit receives a request for stop of reading from said end determination unit.

12. The variable-length decoding device according to claim 1,
wherein said flag buffer control unit is configured to initialize an area of said flag buffer to zero before or after decoding coded data corresponding to the block, the area corresponding to a block.

13. The variable-length decoding device according to claim 1, further comprising
a free space managing unit configured to manage free space in said data buffer and free space in said flag buffer, and issue a request to said variable-length decoding unit for stop of decoding or a permission to said variable-length decoding unit to decode a following block, depending on the free space in said data buffer and the free space in said flag buffer.

14. The variable-length decoding device according to claim 13,
wherein said free space managing unit is configured to issue the permission to said variable-length decoding unit to decode a following block, when said data buffer and said flag buffer have free space at a time when said end determination unit determines that one of the decoded component values is the last component value.

15. The variable-length decoding device according to claim 13,
wherein said flag buffer has a capacity for holding at least 64 flags.

16. The variable-length decoding device according to claim 1,
wherein said data buffer control unit is configured to initialize an area of said data buffer to zero before or after decoding coded data corresponding to the block, the area corresponding to a block.

17. The variable-length decoding device according to claim 15,
wherein said data buffer has an area corresponding to a block which is capable of holding 64 component values.

18. The variable-length decoding device according to claim 13,
wherein said free space managing unit is configured to issue a request to said variable-length decoding unit for stop of decoding when at least one of said data buffer and said flag buffer has no free space.

19. A variable-length decoding device which decodes coded data including a variable-length code into component values composing a block, said device comprising:
a variable-length decoding unit configured to detect and decode a first code, a second code, a third code, and a fourth code from the coded data, the first code being TotalCoeff which indicates the number of nonzero coefficients included in a block, the second code being totalzero which indicates the number of zero coefficients preceding a last nonzero coefficient in the block, the third code being LEVEL which indicates a value of a nonzero coefficient, and the fourth code being run_before which indicates the number of consecutive zero coefficients preceding the LEVEL;
an end determination unit configured to determine a last coefficient among nonzero coefficients in the block, based on the first code and the second code;
a flag buffer which holds flags each of which has a corresponding coefficient among coefficients from a coefficient at a beginning of the block to a coefficient determined as being the last nonzero coefficient by said end determination unit, each of the flags indicating whether the corresponding coefficient is a zero coefficient or a nonzero coefficient;
a data buffer which holds only a nonzero coefficient among decoded coefficients;
a flag buffer control unit configured to set the flags in said flag buffer based on the decoded first code to the fourth code and hold an end address, each of the flags indicating whether the corresponding coefficient among the coefficients from the coefficient at the beginning of the block to the last nonzero coefficient in the block is a zero coefficient or a nonzero coefficient, and the end address being a data buffer address corresponding to the last nonzero coefficient;
a data buffer control unit configured to perform, based on the flags set in said flag buffer, (i) control such that only the nonzero coefficient is written in said data buffer, and (ii) control such that the nonzero coefficient is read from said data buffer; and
a selecting unit configured to select either zero or the coefficient read from said data buffer,
wherein said flag buffer control unit is configured to control the selection by said selecting unit, based on the flags stored in said flag buffer and the end address.

20. A variable-length decoding device which decodes coded data including a variable-length code into component values composing a block, said device comprising:
a variable-length decoding unit configured to detect and decode EOB, LEVEL, and RUN, the EOB being a code which indicates a last nonzero coefficient among nonzero coefficients included in a block, the LEVEL being a code which indicates a value of nonzero coefficient, and the RUN being a code which indicates the number of consecutive zero coefficients preceding a nonzero coefficient;
an end determination unit configured to determine a last coefficient among nonzero coefficients in the block, based on the EOB;
a flag buffer which holds flags each of which has a corresponding coefficient among coefficients from a coefficient at a beginning of the block to a coefficient determined as being the last nonzero coefficient by said end determination unit, each of the flags indicating whether the corresponding coefficient is a zero coefficient or a nonzero coefficient;
a data buffer which holds only a nonzero coefficient among decoded coefficients;
a flag buffer control unit configured to set the flags in said flag buffer based on the LEVEL and the RUN and hold an end address, each of the flags indicating whether the corresponding coefficient among the coefficients from the coefficient at the beginning of the block to the last nonzero coefficient in the block is a zero coefficient or a nonzero coefficient, and the end address being a data buffer address corresponding to the last nonzero coefficient;
a data buffer control unit configured to perform, based on the flags set in said flag buffer, control such that only the nonzero coefficient is written in said data buffer, and control such that the nonzero coefficient is read from said data buffer; and
a selecting unit configured to select either zero or the coefficients read from said data buffer,
wherein said flag buffer control unit is configured to control the selection by said selecting unit, based on the flags stored in said flag buffer and the end address.
